(19) United States
(12) Patent Application Publication
(10) Pub. No.: US 2024/0162840 A1
(43) Pub. Date: May 16, 2024

(54) METHOD FOR CONTROLLING A PIEZOELECTRIC DRIVE UNIT

(71) Applicant: ROBERT BOSCH GMBH, Stuttgart (DE)

(72) Inventors: Frank Schatz, Kornwestheim (DE); Hendrik Specht, Pliezhausen (DE)

(21) Appl. No.: 18/550,657

(22) PCT Filed: Jun. 22, 2022
(86) PCT No.: PCT/EP2022/066984

§ 371 Date: Sep. 14, 2023

(30) Foreign Application Priority Data
Jul. 28, 2021 (DE) 10 2021 208 125.8

(51) Int. Cl. H02N 2/14; G02B 26/08

(52) U.S. Cl. CPC H02N 2/142; G02B 26/0858

(57) ABSTRACT

The invention relates to a method for controlling a piezoelectric drive unit (81). For this purpose, a first control signal is applied to a first electrode (90a) of the first piezo element (95) of the piezoelectric drive unit (81). Additionally, a second control signal is applied to a second electrode (90b) of the first piezo element (95) of the piezoelectric drive unit (81). The first control signal is configured as a continuous positive first voltage signal. The second control signal is configured as a constant second voltage signal. The first control signal is always greater than the second control signal.

### FIELD

The present invention relates to a method for controlling a piezoelectric drive unit. In addition, the present invention relates to a circuit configuration for controlling a piezoelectric drive unit and a micromechanical oscillating system.

### BACKGROUND INFORMATION

In conventional piezoelectric drives for micromirrors, usually a thin PZT layer is applied onto a silicon element. Applying a voltage on the thin layer changes its thickness and its lateral extension. Similar to the case of a bimetal subjected to temperature, the overall system of silicon and PZT is bent when subjected to voltage, which is used for driving the mirror. In the case of such a piezoelectric drive, it is undesirable to have a bipolar drive, in which the voltage signal is periodically alternating in the positive and negative voltage range and in which the coercive field is comparatively small, since this results in a doubling of the movement frequency of the converter.

For producing a unipolar drive, European Patent Application No. EP 3220183 A1 describes a drive, in which a piezo element is controlled using a periodic signal and a control circuit ensures that the minimum of this signal never falls below 0 volt.

An object of the present invention is to provide a simplified method for controlling a piezoelectric drive unit.

### SUMMARY

The present invention provides a method for controlling a piezoelectric drive unit. In addition, a circuit configuration for controlling a piezoelectric drive unit and a micromechanical oscillating system are provided.

According to an example embodiment of the present invention, in the method for controlling a piezoelectric drive unit, initially a first control signal is applied to a first electrode of a first piezo element of the piezoelectric drive unit. The first electrode is in particular the first upper electrode of the first piezo element. Furthermore, a second control signal is applied to a second electrode of the first piezo element of the piezoelectric drive unit. The second electrode is in particular a second lower electrode of the piezo element. The first and second electrodes are situated opposite each other and an electric field is built up between the two electrodes by application of a respective voltage. For this purpose, the first control signal is configured as a, particularly continuous, positive first voltage signal. The second control signal, by contrast, is configured as a constant second voltage signal. The first control signal is always greater than the second control signal. This means that the value of the first voltage signal is always greater than the value of the second voltage signal. This is not based on the absolute value of the respective voltage signal; rather, negative control signals or voltage signals may also exist. Thus, for example, a periodic first voltage signal, which progresses continuously between 0.5 volt and 1.5 volt, is to be regarded as a greater control signal than a constant second voltage signal, which progresses constantly at −3 volt. The control signals may also be called drive signals. The described control method produces a unipolar drive of the piezoelectric drive unit. In this connection, it is advantageous that the polarization of the material is not reversed in each period. This change of polarity can result in a deterioration of the material properties and in an increased energy consumption. In addition, the described varied control of the first and second electrodes makes it readily possible to adjust the magnitude of the electric field between the two electrodes of the piezo element and thus set a defined operating point. In order to avoid the effects of the hysteresis behavior in the range of small electric fields and thus small voltages (hysteresis always means that the behavior depends on the previous history), one likes to operate piezoelectric materials at a defined operating point, at which a defined field above the hysteresis prevails and the drive is then operated with a smaller amplitude around this field. The piezoelectric coefficient e31 is a function of the operating point. For a suitable operating point, one obtains more lateral extension per field.

According to an example embodiment of the present invention, the first control signal is preferably generated by an ASIC (application-specific integrated circuit). ASICs are operated at low voltages. The control method makes it possible to use the voltage that the ASIC is able to supply, e.g., 3.3V. Within this voltage range, the signal is generated and applied to the first electrode of the piezo element. In this connection, it is irrelevant whether the range from 1 to 2 V, from 2 to 3 V or 0 to 1 V or even the entire range is used. Hence, it is not necessary to have a control circuit that controls the utilized range. In the case of large quantities, an ASIC is more cost-effective than a discrete circuit. Moreover, a size of an ASIC is, in particular substantially, smaller than the size of a discrete circuit.

According to an example embodiment of the present invention, preferably, the positive first voltage signal is composed of a constant, positive third voltage signal and a periodically progressing positive fourth voltage signal. Preferably, in this connection, the constant, positive third voltage signal is applied to a voltage reference point of the ASIC. The voltage reference point of the ASIC is thus raised with respect to the circuit ground. Alternatively, the constant, positive third voltage signal is applied to an analog front end of the ASIC. The voltage reference point of the analog front end of the ASIC is thus raised with respect to the circuit ground. Preferably, the constant, positive third voltage signal is generated by a first constant voltage source. The first constant voltage source is preferably integrated in the ASIC. Alternatively, the first constant voltage source is preferably situated outside of the ASIC. The second control signal is preferably constant at 0 V, that is, it is at circuit ground.

According to an example embodiment of the present invention, the second control signal is preferably generated by a second, in particular external, constant voltage source. The constant second voltage signal here has a constant negative voltage. Setting the operating point of the first piezo element is thus made possible by the second constant voltage source, the potential of which is applied to the second electrode of the actuator. This potential is negative with regard to the potential of the first control signal, in particular of the ground of the ASIC. The magnitude of the potential may be chosen freely and is set depending on the desired operating point.

Since it uses a constant voltage source that is independent of the first control signal, in particular of the ASIC, the magnitude is also freely selectable.

According to an example embodiment of the present invention, the first voltage signal preferably progresses in periodic fashion. In this context, the first voltage signal preferably progresses in sinusoidal fashion. Alternatively, the first voltage signal progresses in parabolic fashion as a truncated sinusoidal signal. As a further alternative, the first voltage signal progresses in rectangular fashion.

The method according to the present invention is preferably used for controlling a piezoelectric drive unit of a micromirror. In this connection, the first piezo element is preferably controlled in such a way that the micromirror moves about a first and/or second axis of rotation of the micromirror, in particular in resonant fashion. In this connection, the method is used to control a piezoelectric drive unit of a micromirror having a first wing pair and a second wing pair. The first piezo element is in this case developed as a first PZT layer with the first electrode and the second electrode. The first PZT layer is disposed only on the first or alternatively on the second wing pair. Furthermore, the piezoelectric drive unit of the micromirror additionally has a second PZT layer as a second piezo element having a third electrode, in particular a third upper electrode, and a fourth electrode, in particular a fourth lower electrode. In this case, the first PZT layer is disposed on the first and the second PZT layer on the second wing pair. In addition to the first and second control signals, which are applied to the first piezo element, a third control signal is applied to the third electrode of the second PZT layer. In addition, a fourth control signal is applied to the fourth electrode of the second PZT layer. Here, the third control signal is configured as a, particularly continuous, positive fifth voltage signal. The fourth control signal, by contrast, is configured as a constant sixth voltage signal. The third control signal is always greater than the fourth control signal. Since, due to the strain curve, PZT can only be moved in one direction, a wing cannot be pushed downward in a de-energized state. For this reason, both wings are preferably first bent upward at a fundamental voltage. Subsequently, the wing may also be bent downward from this new rest state reducing the voltage. In order for the wings to oscillate oppositely with respect to each other, the positive first voltage signal and the positive fifth voltage signal progress in a temporally offset manner, in particular offset by 180°, relative to each other. The first and fifth voltage signals preferably have the same frequency.

A further subject matter of the present invention is a circuit configuration for controlling a piezoelectric drive unit. According to an example embodiment of the present invention, the circuit configuration in this case has a first signal-generating unit, which is used to generate a first control signal for a first electrode, in particular a first upper electrode, of a first piezo element of the piezoelectric drive unit. The circuit configuration additionally has a second signal-generating unit, which is used to generate a second control signal for a second electrode, in particular a second lower electrode, of the first piezo element of the piezoelectric drive unit. The first signal-generating unit is designed to generate the first control signal in such a way that the first control signal is configured as a, particularly continuous, positive first voltage signal. The second signal-generating unit is designed to generate the second control signal in such a way that the second control signal is configured as a constant second voltage signal. The first control signal is always greater than the second control signal.

According to an example embodiment of the present invention, preferably, the first signal-generating unit is configured as an ASIC. Preferably, the circuit configuration in this connection additionally comprises a third constant voltage source, which is connected to the ASIC and supplies the ASIC with a constant seventh voltage signal. The constant seventh voltage signal is in this connection also called the fundamental voltage of the ASIC. From the constant seventh voltage signal, the ASIC internally generates a periodically progressing positive fourth voltage signal. In addition, the circuit configuration also comprises a first constant voltage source, which is connected to the ASIC and generates a constant, positive third voltage signal. The positive first voltage signal is in this instance composed of the third voltage signal and the fourth voltage signal. Alternatively, the circuit configuration additionally comprises a second constant voltage source for generating the second control signal. The constant second voltage signal here has a constant negative voltage.

A further subject matter of the present invention is a micromechanical oscillating system having a micromirror, a piezoelectric drive unit, in particular of the micromirror, and an above-described circuit configuration for controlling the piezoelectric drive unit, according to the present invention.

### BRIEF DESCRIPTION OF THE DRAWINGS

FIG. 1 shows a first specific embodiment of a method for controlling a piezoelectric drive unit, according to the present invention.

FIG. 2A schematically shows a first specific embodiment of a circuit configuration for controlling a piezoelectric drive unit, according to the present invention.

FIG. 2B schematically shows a second specific embodiment of a circuit configuration for controlling a piezoelectric drive unit, according to the present invention.

FIG. 2C schematically shows a third specific embodiment of a circuit configuration for controlling a piezoelectric drive unit, according to the present invention.

FIG. 3 schematically shows a micromechanical oscillating system.

FIG. 4A shows a first sinusoidal progression of a first, second, third and fourth control signal for electrodes of a piezo element, according to an example embodiment of the present invention.

FIG. 4B shows a second sinusoidal progression of a first, second, third and fourth control signal for electrodes of a piezo element, according to an example embodiment of the present invention.

### DETAILED DESCRIPTION OF EXAMPLE EMBODIMENTS

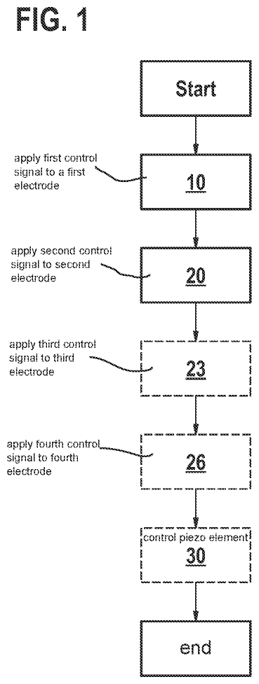

FIG. 1 schematically shows in the form of a flow chart a first specific embodiment of a method for controlling a piezoelectric drive unit. In a method step 10, a first control signal is applied to a first electrode, in particular a first upper electrode, of a first piezo element of the piezoelectric drive unit. For this purpose, the first control signal is configured as a, particularly continuous, positive first voltage signal. In a subsequent method step 20, a second control signal is applied to a second electrode, in particular a second lower electrode, of the first piezo element of the piezoelectric drive unit. The second control signal is configured as a constant second voltage signal. The first control signal is always greater than the second control signal.

Optionally, the first control signal is generated in method step by an ASIC.

Furthermore optionally, the positive first voltage signal is composed of a constant, positive third voltage signal and a periodically progressing positive fourth voltage signal.

Furthermore optionally, the constant, positive third voltage signal is applied to a voltage reference point of the ASIC. Alternatively, the constant, positive third voltage signal is applied to an analog front end of the ASIC. Furthermore optionally, the constant, positive third voltage signal is generated by a first constant voltage source. The second control signal optionally is constantly 0 V.

Alternatively, the second control signal is optionally generated by a second, in particular external, constant voltage source. The constant second voltage signal here has a constant negative voltage.

Optionally, the first voltage signal progresses in periodic fashion.

The method is optionally used for controlling a piezoelectric drive unit of a micromirror. In this connection, in an optional method step 30 following method step 20, the first piezo element is controlled in such a way that the micromirror moves about a first and/or second axis of rotation of the micromirror, in particular in resonant fashion. Optionally, the method is used to control a piezoelectric drive unit of a micromirror having a first wing pair and a second wing pair. The first piezo element is in this case developed as a first PZT layer with the first electrode and the second electrode. The PZT layer is situated only on the first wing pair.

Furthermore optionally, the piezoelectric drive unit of the micromirror additionally has a second PZT layer as a second piezo element having a third electrode, in particular a third upper electrode, and a fourth electrode, in particular a fourth lower electrode. The second PZT layer is situated on the second wing pair. In this connection, in an optional method step 23 following method step 20, a third control signal is applied to the third electrode of the second PZT layer. The third control signal is configured as a, particularly continuous, positive fifth voltage signal. In an optional method step 26 following method step 23, a fourth control signal is applied to the fourth electrode of the second PZT layer. The fourth control signal is configured as a constant sixth voltage signal. The third control signal is always greater than the fourth control signal. Optionally, the fourth control signal corresponds to the second control signal. Optionally, the positive first voltage signal and the positive fifth voltage signal progress in a temporally offset manner, in particular offset by 180°, relative to each other.

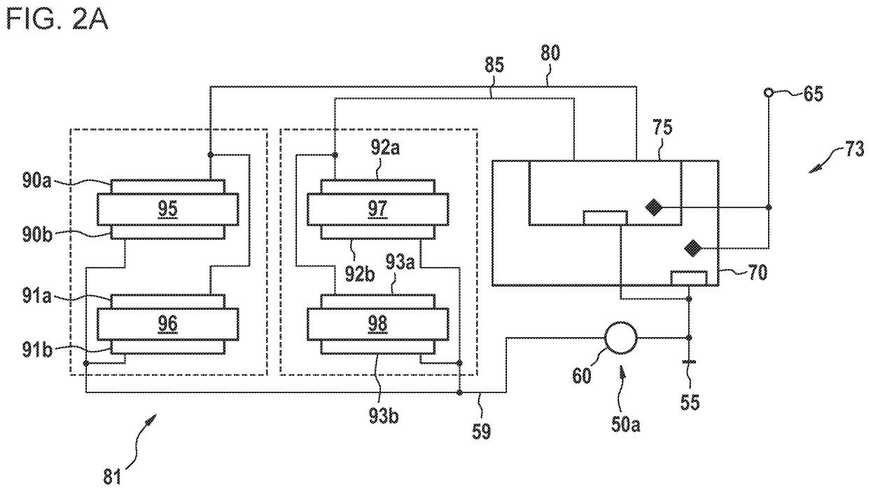

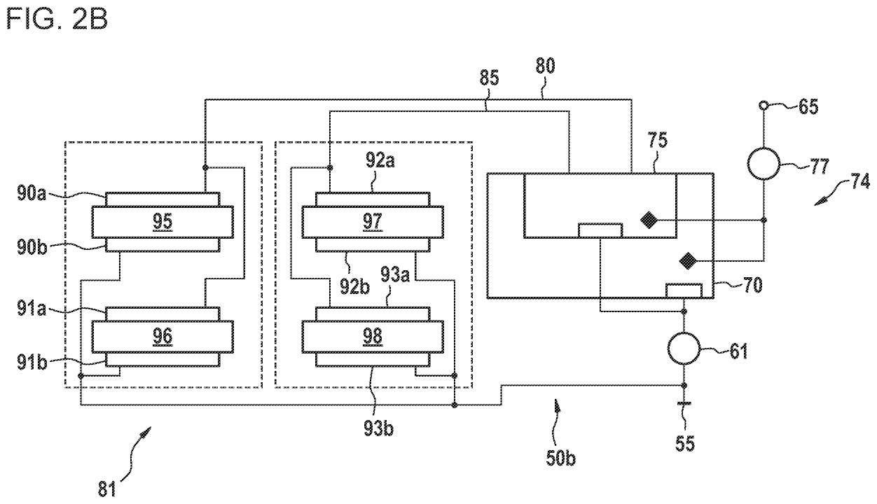

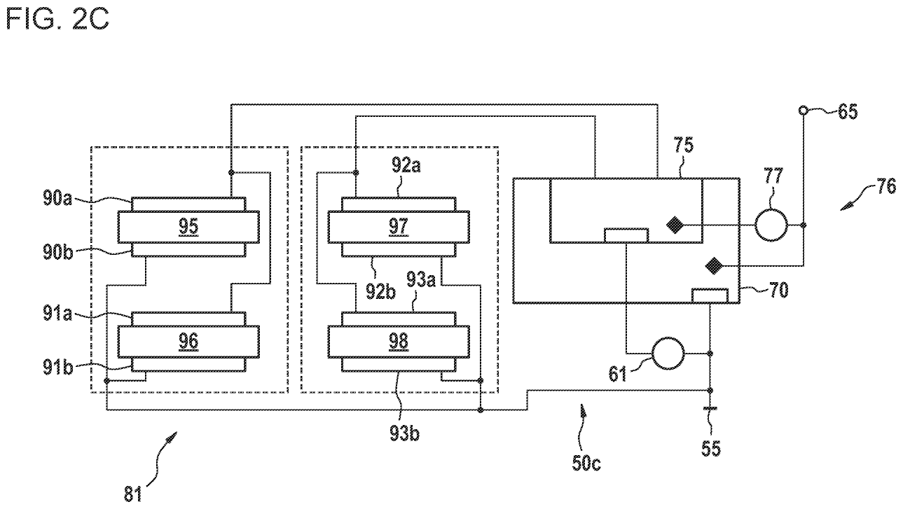

FIG. 2A schematically shows a first specific embodiment of a circuit configuration 73 for controlling a piezoelectric drive unit 81. The circuit configuration 73 in this instance has a first signal-generating unit 70 for generating a first control signal for a first upper electrode 90a of a first piezo element 95 of the piezoelectric drive unit 81. The first control signal is transmitted to the first electrode 90a via a first line 80. In addition, the circuit configuration 73 has a second signal-generating unit 50a for generating a second control signal for a second lower electrode 90b of the first piezo element 95 of the piezoelectric drive unit 81. The second control signal is transmitted to the second electrode 90b via a second line 59. The first signal-generating unit 70, which is here configured as an ASIC, is designed to generate the first control signal in such a way that the first control signal is configured as a, particularly continuous, positive first voltage signal. The second signal-generating unit 50a is designed to generate the second control signal in such a way that the second control signal is configured as a constant second voltage signal. The first control signal is always greater than the second control signal. In this first specific embodiment, the second signal-generating unit 50a is developed as a second constant voltage source 60 for generating the second control signal. The constant second voltage signal here has a constant negative voltage. In this specific embodiment, the circuit configuration 73 is designed to control a piezoelectric drive unit 81 of a micromirror (not shown here) having a first wing pair and a second wing pair. On each of the four wings, one of the PZT layers 95, 96, 97 and 98 is situated with the respective upper electrodes 90a, 91a, 92a and 93a and the lower electrodes 90b, 91b, 92b and 93b. The first signal-generating unit 70 controls the upper electrodes 90a and 91a of the PZT layers 95 and 96 by way of the first control signal. For controlling the upper electrodes 92a and 93a of the PZT layers 97 and 98, the first signal-generating unit 70 generates a third control signal, which is configured as a, particularly continuous, positive fifth voltage signal and is transmitted to the upper electrodes 92a and 93a via the line 85. The lower electrodes 93b and 92b are controlled by a fourth control signal, which in this case corresponds to the second control signal. The circuit ground is applied at point 55 of circuit configuration 73. The ASIC is connected at the third constant voltage source 65 and has an analog front end 75.

FIG. 2B schematically shows a second specific embodiment of a circuit configuration 74 for controlling the piezoelectric drive unit 81. In this case, in contrast to the first specific embodiment, circuit configuration 74 has a first constant voltage source 61, which is connected to the ASIC as the first signal-generating unit 70 and generates a constant, positive third voltage signal. The ASIC is furthermore connected to the third constant voltage source 65, which generates a constant seventh voltage signal as the so-called fundamental voltage, from which the ASIC internally generates a periodically progressing positive fourth voltage signal. The positive first voltage signal is thus composed of the third voltage signal and the fourth voltage signal. The voltage reference point of the ASIC as a whole is thus raised with respect to the circuit ground 55. The further constant voltage source 77 is used to readjust the potential at the ASIC shifted by the voltage source 61 also for the voltage supply of the ASIC. The further constant voltage source 77 thus supplies a constant, positive voltage signal at the level of the third voltage signal in order thus to raise also the potential of the ASIC with respect to the circuit ground 55. The second signal-generating unit 50b is applied to circuit ground 55 and thus supplies a constant second voltage signal of 0 V.

FIG. 2C schematically shows a third specific embodiment of a circuit configuration 76 for controlling the piezoelectric drive unit 81. In this case, in contrast to the second specific embodiment, the first constant voltage source 61 is connected to the analog front end 75 of the ASIC. The voltage reference point of the analog front end 75 of the ASIC is thus raised with respect to the circuit ground 55. Here too, the second signal-generating unit 50b is connected to circuit ground 55 and thus supplies a constant second voltage signal of 0 V.

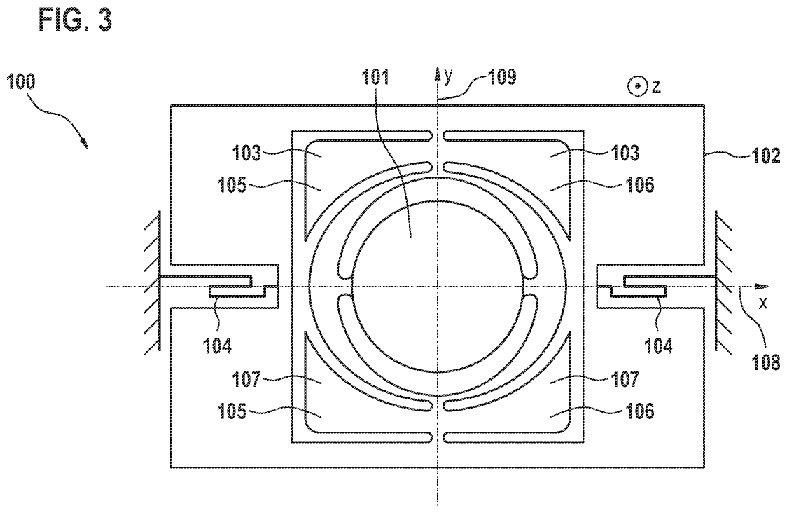

In a top view, FIG. 3 schematically shows a micromechanical oscillating system 100 comprising a micromirror 101 and a piezoelectric drive unit of the micromirror 101. In addition, the micromechanical oscillating system 100 includes a circuit configuration (not shown here) for controlling the piezoelectric drive unit. Micromirror 101 has a first wing pair 105 and a second wing pair 106. A second PZT layer is respectively applied on the third wing pair 105 as the first piezo element 103. A second PZT layer is respectively applied on the second wing pair 106 as the second piezo element 107. The micromirror 101 is connected to a frame element 102 via two spring elements 104. The piezoelectric drive unit is controlled by the circuit configuration in such a way that the micromirror 101 moves resonantly about a first 108 and/or second axis of rotation 109 of the micromirror 101.

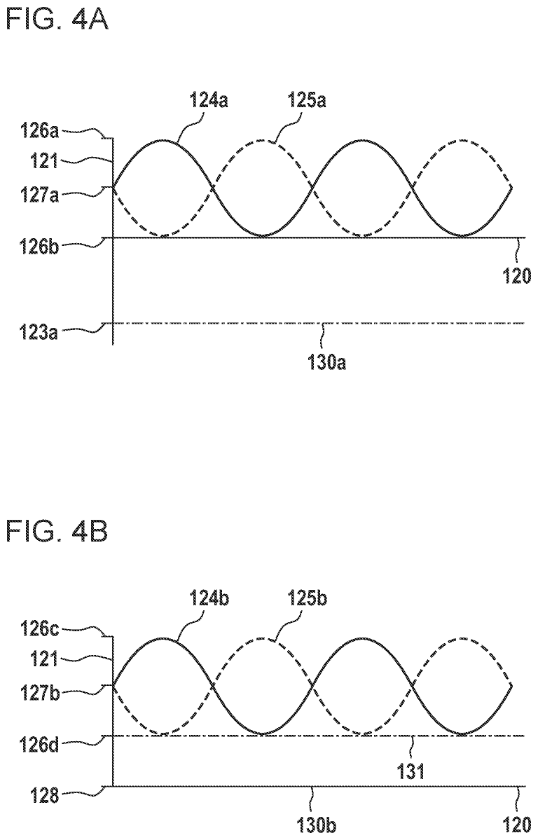

FIG. 4A shows a first and a second sinusoidal progression of a first 124a, second 130a, third 125a and fourth control signal for electrodes of a respective piezo element of a piezoelectric drive unit for a micromirror having a first wing pair and a second wing pair. In particular, the illustrated control signal describe a possible progression of the control signals for the electrodes of the PZT layers 95, 96, 97 and 98 from FIG. 2A. The voltage in volts is plotted on the Y axis 121, and the time in seconds is plotted on the X axis. In order for the wings to oscillate in opposite directions, the first sinusoidal control signal 124a is applied to the upper electrodes of the third wing pair and, on the upper electrodes of the second wing pair, the third sinusoidal control signal 125a is applied at the same frequency but offset by 180° with respect to the first sinusoidal control signal 124a. In this exemplary embodiment, the first control signal 124a as the first voltage signal progresses alternately between the Y axis sections 126b and 126a and is configured as a continuous, positive voltage signal. The Y axis section 126a may be 0.1 V, for example, and the Y axis section 126b may be 3 V. In this exemplary embodiment, the third control signal 125a as the fifth voltage signal likewise progresses alternately between the Y axis sections 126b and 126a and is configured as a continuous, positive voltage signal. In this exemplary embodiment, the first and the third control signals are generated by an ASIC. In order to allow for a unipolar drive of the piezoelectric drive unit, a second control signal 130a is applied to the lower electrodes of the first wing pair. The second control signal 130a is configured as a constant second voltage signal, which in this exemplary embodiment has a constant negative voltage and progresses through the Y axis section 123a. The first control signal 124a is thus always greater than the second control signal 130a. A fourth control signal is applied to the lower electrodes of the second wing pair, which in this case corresponds to the second control signal 130a.

FIG. 4B, in contrast, shows the possible progression of the first 124b, second 130b, third 125b and fourth control signals for the electrodes of the PZT layers 95, 96, 97 and 98 from FIG. 2B or 2C. In this case, the first control signal 124b progresses as a continuous positive first voltage signal alternating between the Y axis sections 126c and 126d. In order to allow for a unipolar drive, in this exemplary embodiment, the positive first voltage signal is composed of a constant, positive third voltage signal 131 and a sinusoidally progressing positive fourth voltage signal. The constant positive third voltage signal runs in this case through the Y axis section 126d. The Y axis section 126d may be 5 V, for example, and the Y axis section 126c may be 8 V. In this exemplary embodiment, the third control signal 125b as the fifth voltage signal likewise progresses alternately between the Y axis sections 126c and 126d and is again configured as a continuous, positive fifth voltage signal. The positive fifth voltage signal is in this case also composed of a constant and a sinusoidal voltage signal. The Y axis section 128 indicates the circuit ground and in this case the second control signal 130b, and the fourth control signal.

1-18. (canceled)

19. A method for controlling a piezoelectric drive unit, the method comprising the following steps:
applying a first control signal to a first upper electrode of a first piezo element of the piezoelectric drive unit; and
applying a second control signal to a second lower electrode of the first piezo element of the piezoelectric drive unit;
wherein the first control is configured as a continuous, positive first voltage signal, and the second control signal is configured as a constant second voltage signal, the first control signal always being greater than the second control signal.

20. The method as recited in claim 19, wherein the first control signal is generated by an ASIC.

21. The method as recited in claim 20, wherein the positive first voltage signal is composed of a constant, positive third voltage signal and a periodically progressing positive fourth voltage signal.

22. The method as recited in claim 21, wherein the constant, positive third voltage signal is applied to a voltage reference point of the ASIC.

23. The method as recited in claim 21, wherein the constant, positive third voltage signal is applied to an analog front end of the ASIC.

24. The method as recited in claim 21, wherein the constant, positive third voltage signal is generated by a first constant voltage source.

25. The method as recited in claim 19, wherein the second control signal is constant at 0 V.

26. The method as recited in claim 19, wherein the second control signal is generated by a second external, constant voltage source, the constant second voltage signal having a constant negative voltage.

27. The method as recited in claim 19, wherein the first voltage signal progresses periodically, in sinusoidal or rectangular or parabolic fashion.

28. The method as recited in claim 19, wherein the method is used for controlling a piezoelectric drive unit of a micromirror.

29. The method as recited in claim 28, wherein the piezoelectric drive unit has a first wing pair and a second wing pair, the first piezo element being configured as a first PZT layer including the first electrode and the second electrode, the first PZT layer being situated only on the first or the second wing pair.

30. The method as recited in claim 29, wherein the piezoelectric drive unit of the micromirror additionally has a second PZT layer as a second piezo element including a third upper electrode, and a fourth lower electrode, the first PZT layer being situated on the first wing pair and the second PZT layer being situated on the second wing pair, and the method further comprises:
applying a third control signal to the third upper electrode of the second PZT layer; and
applying a fourth control signal to the fourth lower electrode of the second PZT layer;
wherein the third control signal is configured as a continuous, positive fifth voltage signal, and the fourth control signal is configured as a constant sixth voltage signal, the third control signal always being greater than the fourth control signal.

31. The method as recited in claim 30 wherein the positive first voltage signal and the positive fifth voltage signal progress in a temporally offset manner, the temporal offset being 180° relative to each other.

32. A circuit configuration for controlling a piezoelectric drive unit, comprising:
a first signal-generating unit configured to generate a first control signal for a first upper electrode of a first piezo element of the piezoelectric drive unit; and
a second signal-generating unit configured to generate a second control signal for a second lower electrode of the first piezo element of the piezoelectric drive unit;
wherein the first signal-generating unit is configured to generate the first control signal in such a way that the first control signal is configured as a continuous, positive first voltage signal, and the second signal-generating unit is configured to generate the second control signal in such a way that the second control signal is configured as a constant second voltage signal, the first control signal always being greater than the second control signal.

33. The circuit configuration as recited in claim 32, wherein the first signal-generating unit is configured as an ASIC.

34. The circuit configuration as recited in claim 33, further comprising:
a third, constant voltage source which is connected to the ASIC and generates a constant seventh voltage signal, the ASIC generating from the constant seventh voltage signal a periodically progressing positive fourth voltage signal; and
a first constant voltage source which is connected to the ASIC and generates a constant, positive third voltage signal;
wherein the positive first voltage signal is composed of the third voltage signal and the fourth voltage signal.

35. The circuit configuration as recited in claim 32, wherein the circuit configuration further comprises a second constant voltage source configured to generate the second control signal, the constant second voltage signal having a constant negative voltage.

36. A micromechanical oscillating system, comprising:
a micromirror;
a piezoelectric drive unit of the micromirror; and
a circuit configuration configured to control the piezoelectric drive unit, the circuit configuration including:
a first signal-generating unit configured to generate a first control signal for a first upper electrode of a first piezo element of the piezoelectric drive unit, and
a second signal-generating unit configured to generate a second control signal for a second lower electrode of the first piezo element of the piezoelectric drive unit,
wherein the first signal-generating unit is configured to generate the first control signal in such a way that the first control signal is configured as a continuous, positive first voltage signal, and the second signal-generating unit is configured to generate the second control signal in such a way that the second control signal is configured as a constant second voltage signal, the first control signal always being greater than the second control signal.
